(19) United States
(12) Patent Application Publication
(10) Pub. No.: US 2006/0250559 A1
(43) Pub. Date: Nov. 9, 2006

(54) Glass product for use in ultra-thin glass display applications

(76) Inventors: Peter L. Bocko, Painted Post, NY (US); Frank T. Coppola, Elmira, NY (US); Victoria A. Edwards, Horseheads, NY (US); Gunilla E. Gillberg, Painted Post, NY (US); Josef C. Lapp, Corning, NY (US); Monica J. Mashewske, Horseheads, NY (US); Robert G. Schaeffler, Pine City, NY (US); David A. Tammaro, Painted Post, NY (US)

Correspondence Address: CORNING INCORPORATED, SP-TI-3-1, CORNING, NY, 14831, US

(21) Appl. No.: 11/485,201

(22) Filed: Jul. 12, 2006

Related U.S. Application Data
(63) Continuation of application No. 10/613,972, filed on Jul. 3, 2003.

(51) Int. Cl. C30B 33/00; C09K 19/00; B44C 1/22; G02F 1/1343

(52) U.S. Cl. 349/139; 216/23; 428/1.1; 216/88

(57) ABSTRACT

The present invention is directed to a substrate product for use in the manufacture of active matrix liquid crystal display panels. The product includes a display substrate suitable for use as a display panel. The display substrate has a thickness less than or equal to 0.4 mm, a composition that is substantially alkali free, and a surface smoothness that allows the direct formation of thin-film transistors thereon without a prior processing step of polishing and/or grinding. The product also includes at least one support substrate removably attached to the display substrate.

### BACKGROUND OF THE INVENTION

1. Field of the Invention

The present invention relates generally to glass substrates, and particularly to a glass substrate product for use in AMLCD display manufacturing processes.

2. Technical Background

Liquid crystal displays (LCDs) are non-emissive displays that use external light sources. An LCD is a device that may be configured to modulate an incident polarized light beam emitted from the external source. LC material within the LCD modulates light by optically rotating the incident polarized light. The degree of rotation corresponds to the mechanical orientation of individual LC molecules within the LC material. The mechanical orientation of the LC material is readily controlled by the application of an external electric field. This phenomena is readily understood by considering a typical twisted nematic (TN) liquid crystal cell.

A typical TN liquid crystal cell includes two substrates and a layer of liquid crystal material disposed therebetween. Polarization films, oriented 90° one to the other, are disposed on the outer surfaces of the substrates. When the incident polarized light passes through the polarization film, it becomes linearly polarized in a first direction (e.g., horizontal, or vertical). With no electric field applied, the LC molecules form a 90° spiral. When incident linearly polarized light traverses the liquid crystal cell it is rotated 90° by the liquid crystal material and is polarized in a second direction (e.g., vertical, or horizontal). Because the polarization of the light was rotated by the spiral to match the polarization of the second film, the second polarization film allows the light to pass through. When an electric field is applied across the liquid crystal layer, the alignment of the LC molecules is disrupted and incident polarized light is not rotated. Accordingly, the light is blocked by the second polarization film. The above described liquid crystal cell functions as a light valve. The valve is controlled by the application of an electric field. Those of ordinary skill in the art will also understand that, depending on the nature of the applied electric field, the LC cell may also be operated as a variable light attenuator.

An Active Matrix LCD (AMLCD) typically includes several million of the aforementioned LC cells in a matrix. Referring back to the construction of an AMLCD, one of the substrates includes a color filter plate and the opposing substrate is known as the active plate. The active plate includes the active thin film transistors (TFTs) that are used to control the application of the electric field for each cell or subpixel. The thin-film transistors are manufactured using typical semiconductor type processes such as sputtering, CVD, photolithography, and etching. The color filter plate includes a series of red, blue, and green organic dyes disposed thereon corresponding precisely with the subpixel electrode area of the opposing active plate. Thus, each sub-pixel on the color plate is aligned with a transistor controlled electrode disposed on the active plate, since each sub-pixel must be individually controllable. One way of addressing and controlling each sub pixel is by disposing a thin film transistor at each sub pixel.

The properties of the aforementioned substrate glass are extremely important. The physical dimensions of the glass substrates used in the production of AMLCD devices must be tightly controlled. The fusion process, described in U.S. Pat. No. 3,338,696 (Dockerty) and U.S. Pat. No. 3,682,609 (Dockerty), is one of the few processes capable of delivering substrate glass without requiring costly post substrate forming finishing operations, such as lapping, grinding, and polishing. Further, because the active plate is manufactured using the aforementioned semiconductor type processes, the substrate must be both thermally and chemically stable. Thermal stability, also known as thermal compaction or shrinkage, is dependent upon both the inherent viscous nature of a particular glass composition (as indicated by its strain point) and the thermal history of the glass sheet, which is a function of the manufacturing process. Chemical stability implies a resistance to the various etchant solutions used in the TFT manufacturing process.

Currently, there is a demand for larger and larger display sizes. This demand, and the benefits derived from economies of scale, are driving AMLCD manufacturers to process larger sized substrates. However, this raises several issues. First, the increased weight of the larger display is problematic. While consumers want larger displays, there is also a demand for lighter and thinner displays. Unfortunately, if the thickness of the glass is decreased, the elastic sag of the glass substrate becomes a problem. The sag is further exacerbated when the size of the substrate is increased to make larger displays. Presently, it is difficult for TFT manufacturing technology to accommodate fusion glass thinner that 0.5 mm because of glass sag. Thinner, larger substrates have a negative impact on the processing robotics' ability to load, retrieve, and space the glass in the cassettes used to transport the glass between processing stations. Thin glass can, under certain conditions, be more susceptible to damage, lending to increased breakage during processing.

In one approach that has been considered, a thick display glass substrate is employed during TFT processing. After the active layer is disposed on the glass substrate, the opposite face of the glass substrate is thinned by grinding and/or polishing. One drawback to this approach is that it requires an additional grinding/polishing step. The expense of the additional step(s) is thought to be quite high.

Therefore, it would be highly desirable to provide an ultra-thin fusion glass substrate that would allow for the direct formation of thin-film transistors without having to subject the display substrate to an additional polishing and/or grinding step. Current glass substrate thicknesses are on the order of 0.6-0.7 mm. By decreasing the thickness of the substrate to 0.3 mm, a 50% reduction in weight will be achieved. However, ultra-thin glass has an unacceptably high degree of sag and can be prone to breakage. What is needed is an ultra-thin glass substrate product that may be employed in the state-of-the art TFT manufacturing processes without the aforementioned problems.

### SUMMARY OF THE INVENTION

The present invention addresses the above-described needs. The present invention provides an ultra-thin fusion glass substrate that can be used in conventional TFT manufacturing processes. The glass substrate product of the present invention has a smoothness that allows the direct formation of thin-film transistors without having to perform a polishing or grinding step. The present invention provides ultra-thin glass substrates having a thickness in the range between 0.4 mm and 0.1 mm. One aspect of the present invention is a substrate product for use in the manufacture of active matrix liquid crystal display panels. The product includes a display substrate suitable for use as a display panel. The display substrate has a thickness less than or equal to 0.4 mm, a composition that is substantially alkali free, and a surface smoothness that allows the direct formation of thin-film transistors thereon without a prior processing step of polishing and/or grinding. The product also includes at least one support substrate removably attached to the display substrate.

In another aspect, the present invention includes a method for making a substrate product for use in the manufacture of active matrix liquid crystal display panels. The method includes forming a display substrate suitable for use as a display panel. The display substrate has a thickness less than or equal to 0.4 mm, a composition that is substantially alkali free, and a surface smoothness that allows the direct formation of thin-film transistors thereon without a prior processing step of polishing and/or grinding. At least one support substrate is attached to the display substrate.

In another aspect, the present invention includes a method for making an active matrix liquid crystal display panel. The method includes forming a plurality of display substrates suitable for use as display panels. Each display substrate has a thickness less than or equal to 0.4 mm, a composition that is substantially alkali free, and a surface smoothness that allows the direct formation of thin-film transistors thereon without a prior processing step of polishing and/or grinding. A support substrate is attached to each display substrate. An active matrix liquid crystal display panel is produced using a first display substrate and a second display substrate. Subsequently, the support substrates attached to each of the display substrates are removed.

In another aspect, the present invention includes an active matrix liquid crystal display panel that includes a first display substrate. The first display substrate has a thickness less than or equal to 0.4 mm, a composition that is substantially alkali free, and a surface smoothness that allows the direct formation of thin-film transistors thereon without a prior processing step of polishing and/or grinding. The panel also includes a second display substrate. The second display substrate has a thickness less than or equal to 0.4 mm, a composition that is substantially alkali free, and a surface smoothness that allows the direct formation of thin-film transistors thereon without a prior processing step of polishing and/or grinding. A liquid crystal material is disposed between the first display substrate and the second display substrate.

Additional features and advantages of the invention will be set forth in the detailed description which follows, and in part will be readily apparent to those skilled in the art from that description or recognized by practicing the invention as described herein, including the detailed description which follows, the claims, as well as the appended drawings.

It is to be understood that both the foregoing general description and the following detailed description are merely exemplary of the invention, and are intended to provide an overview or framework for understanding the nature and character of the invention as it is claimed. The accompanying drawings are included to provide a further understanding of the invention, and are incorporated in and constitute a part of this specification. The drawings illustrate various embodiments of the invention, and together with the description serve to explain the principles and operation of the invention.

### BRIEF DESCRIPTION OF THE DRAWINGS

FIG. 1 is a diagrammatic depiction of the substrate product of the present invention in accordance with a first embodiment of the present invention;

FIG. 2 is a diagrammatic depiction of the substrate product of the present invention in accordance with a second embodiment of the present invention;

FIG. 3 is a diagrammatic depiction of the substrate product of the present invention in accordance with a third embodiment of the present invention;

FIG. 4 is a diagrammatic depiction of the substrate product of the present invention in accordance with a fourth embodiment of the present invention;

FIG. 5 is a diagrammatic depiction of an alternate embodiment of the substrate product depicted in FIG. 1;

FIG. 6 is a detail view showing the disposition of a TFT transistor on the display substrate depicted in FIG. 1; and

FIG. 7A-7B are detail views illustrating TFT processing in accordance with the present invention.

### DETAILED DESCRIPTION

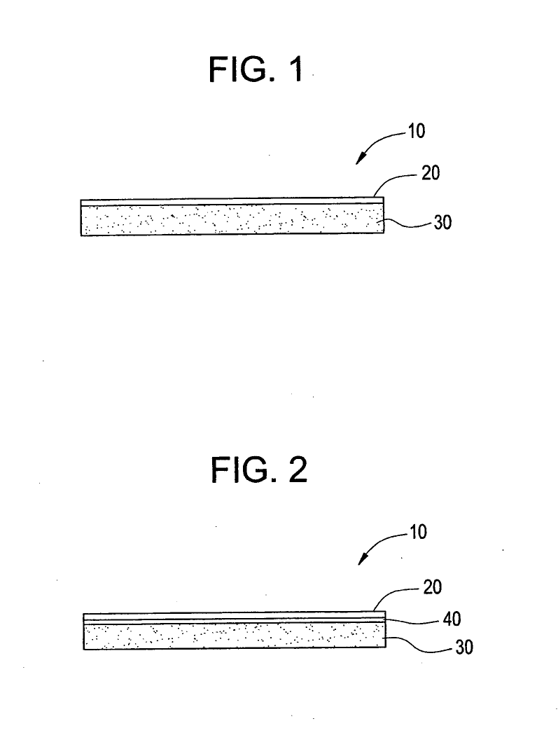

Reference will now be made in detail to the present exemplary embodiments of the invention, examples of which are illustrated in the accompanying drawings. Wherever possible, the same reference numbers will be used throughout the drawings to refer to the same or like parts. An exemplary embodiment of the substrate product of the present invention is shown in FIG. 1, and is designated generally throughout by reference numeral 10.

In accordance with the invention, the present invention is directed to a substrate product for use in the manufacture of active matrix liquid crystal display panels. The product includes a display substrate suitable for use as a display panel. The display substrate has a thickness less than or equal to 0.4 mm, a composition that is substantially alkali free, and a surface smoothness that allows the direct formation of thin-film transistors thereon without a prior processing step of polishing and/or grinding. The product also includes at least one support substrate removably attached to the display substrate. Accordingly, the present invention provides an ultra-thin fusion glass substrate that can be used in state-of-the art TFT manufacturing processes. The display substrate has a smoothness that allows the direct formation of thin-film transistors without having to perform a polishing or grinding step.

As embodied herein, and depicted in FIG. 1, a diagrammatic depiction of the substrate product 10 of the present invention in accordance with a first embodiment of the present invention is disclosed. Substrate product 10 is a glass-on-glass laminate that has an overall thickness in the range between 0.6-0.7 mm. Those skilled in the art will understand that this range is compatible with conventional TFT processing techniques. Product 10 includes display substrate 20 and support substrate 30. Display substrate 20 has a thickness in the range between 0.1 mm and 0.4 mm. The thickness of support substrate 30 depends on the thickness of the display substrate and the overall thickness of product 10.

Display substrate 20 may be of any substrate type suitable for use in a LCD display panel, as long as the display substrate has a thickness less than or equal to 0.4 mm, a composition that is substantially alkali free, and a surface smoothness that allows the direct formation of thin-film transistors thereon without a prior processing step of polishing and/or grinding. Reference is made to U.S. Pat. No. 5,374,595 and U.S. Pat. No. 6,060,168, which are incorporated herein by reference as though fully set forth in their entirety, for a more detailed description of the composition of the glass comprising display substrate 20.

It will be apparent to those of ordinary skill in the pertinent art that modifications and variations can be made to support substrate 30 of the present invention depending on the means used to separate support layer 30 from display substrate 20 after TFT processing is completed. For example, support substrate 30 may be comprised of a sacrificial non-display glass composition (lost glass) suitable for chemical dissolution without subsequent damage to the display substrate. In another embodiment, support substrate 30 may be comprised of a relatively soft non-display glass composition removable by grinding/polishing without subsequent damage to the display substrate. Those of ordinary skill in the art will recognize that many varieties of relatively inexpensive glasses may be used in the production of support layer 30.

A laminate substrate product 10, having surfaces which are essentially defect-free and equivalent in smoothness to polished surfaces, can be fashioned in accordance with the following steps. First, two alkali metal-free batches of different compositions are melted. The batch for the display glass must exhibit a strain point higher than 600° C., and be relatively insoluble in an acid solution. The batch for the support glass substrate consists, expressed in terms of cation percent on the oxide basis, of

| | | | | | |
|---|---|---|---|---|---|
| SiO₂ | 27-47 | B₂O₃ | 0-40 | SrO and/or BaO | 0-10 |
| Al₂O₃ | 15-43 | MgO | 0-4 | ZnO | 0-7 |
| CaO | 5-25 | | | MgO + SrO + BaO + ZnO | 0-15 |

One current candidate for the support glass substrate consists, expressed in terms of cation percent on the oxide basis, of SiO₂ 41, Al₂O₃ 18, B₂O₃ 32 and CaO 9.

Reference is made to U.S. Pat. No. 4,102,664 and U.S. Pat. No. 5,342,426, which are incorporated herein by reference as though fully set forth in their entirety, for a more detailed description of a method for making laminated bodies.

The support glass is at least 1000 times more soluble in the same acid solution and exhibits a linear coefficient of thermal expansion from its setting point to room temperature within about 5×10⁻⁷/° C. of that of the display glass substrate. The support glass also exhibits a strain point higher than 600° C. and relatively close to the strain point of the display glass substrate. The support glass is characterized by a linear coefficient of thermal expansion over the temperature range of 0° C.-300° C. between 20-60×10⁻⁷/° C.

The molten batches are brought together simultaneously while in the fluid state to form a laminated sheet wherein the display glass is essentially completely enclosed within the support glass. The layers are fused together at a temperature where the melts are in fluid form to provide an interface therebetween which is defect-free. The laminated sheet is cooled to solidify each glass present in fluid form.

As discussed above, after TFT processing is completed, an acid solution is used to dissolve the support glass. The resultant surface of the display glass, from which the support glass has been removed, is rendered essentially defect-free and is equivalent in smoothness to a polished glass surface. The dissolution of the soluble glass (lost glass) in an acid bath will be carried out after the laminated sheet has arrived at its destination. Thus, sheets cut from the laminate can be readily stacked and shipped to the LCD display device manufacturer.

The liquidus temperature values of the two glasses will preferably be below the temperature at which lamination is conducted in order to prevent the occurrence of devitrification during the select forming process.

Finally, in accordance with conventional practice, the laminated sheet may be annealed to avoid any detrimental strains, most preferably during the cooling step, although the cooled laminate may be reheated and thereafter annealed. As has been explained above, the strain points of the present inventive glasses are sufficiently high that annealing may not be required in the formation of a-Si devices.

As embodied herein, and depicted in FIG. 2, an alternate embodiment of substrate product 10 of the present invention is disclosed. Again, substrate product 10 has an overall thickness of between 0.6-0.7 mm, which is compatible with current TFT processing techniques. Display substrate 20 has a thickness in the range between 0.1 mm and 0.4 mm. The thickness of support substrate 30 depends on the thickness of the display substrate and the overall thickness of product 10. In this embodiment, support substrate 30 is tacked onto display substrate 20 using adhesive 40. Adhesive 40 is a high temperature flux that is formulated to withstand high temperatures of poly-Si processing, which may approach 450° C. Further, support substrate 30 and adhesive 40 are of a type to withstand the chemical, mechanical, and optical environmental stresses encountered during TFT processing. Reference is made to U.S. Pat. No. 5,281,560 which is incorporated herein by reference as though fully set forth in its entirety, for a more detailed description of possible adhesives.

The composition of display substrate 20 and support substrate 30 were disclosed above in the discussion of the first embodiment. Both display substrate 20 and support substrate 30 may be fabricated using fusion draw processes. Reference is made to U.S. Pat. No. 3,338,696 and U.S. Pat. No. 3,682,609, which are incorporated herein by reference as though fully set forth in their entirety, for a more detailed explanation of a system and method for producing glass substrates using the fusion draw technique. By using higher gear ratio drives and composite pulling rolls, the fusion draw technique is well able to produce glass substrates having a thickness of approximately 100 microns (0.1 mm). One advantage of using a fusion glass as a support substrate is its superior flatness. The flatness of the surface is important because it minimizes focusing errors during the photolithographic steps performed during TFT processing. Further the linear coefficient of thermal expansion (CTE) of support substrate 30 can be made to match that of the display glass. If the substrates have dissimilar CTEs, product warping may occur. Another advantage of using the fusion draw process is the ability to make a support substrate having a higher modulus of elasticity.

The above described second embodiment has the same advantages as the first embodiment. Substrate product 10 has an overall thickness, weight, and sag characteristics that are compatible with state-of-the art TFT processing. The use of sacrificial support layer 30 enables the fabrication of lighter and thinner display panels.

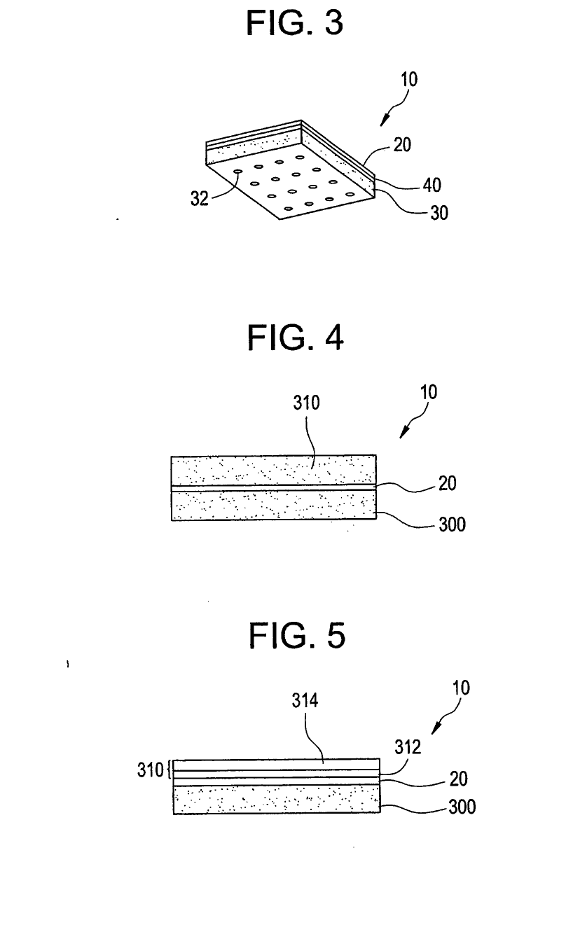

Referring to FIG. 3, another alternate embodiment of the present invention is disclosed. In this embodiment, support substrate 30 is a fusion glass sheet having holes 32 drilled through the glass perpendicular to the surface of the substrate. The size and number of holes depends on the release mechanism used to separate product 10 from the processing station. In one embodiment, the release mechanism employs lifting pins made from a soft non-abrasive material such as Teflon. In another embodiment, the release mechanism applies gas or liquid to lift the substrate. The physical configuration of support substrate 30 may also include corrugation or “egg crate” designs. Support substrate 30 may also be comprised of recyclable glass. After processing, substrate 30 may be ground into cullet and reformed using one of the above described fabrication techniques. Substrate 30 may also be re-used without being ground into cullet.

In another embodiment, support substrate 30 includes a lip that surrounds display substrate 20. In this embodiment, a vacuum may be applied to the display substrate 20 via holes 32 to keep product 10 in place during processing. In this embodiment, adhesive 40 may not be necessary. However, if no adhesive is applied, a diamond like coating (DLC) is applied to the surface of support substrate 30 on which display substrate 20 rests. The DLC aids in the distribution of heat, is scratch resistant, and allows the display substrate 20 to be easily released after processing. In this embodiment, a gas or liquid may be applied to release display substrate 20.

As embodied herein, and depicted in FIG. 4, yet another embodiment of the present invention is disclosed. Substrate 10 includes display substrate 20 coated on both sides with lost glass substrates 300 and 302. This embodiment provides additional protection to display substrate 20. Prior to TFT processing and disposition, one of the support layers is removed. After TFT processing, the second layer is removed and the plastic polarization film is applied to the backside of display substrate 20. As described above, the properties of the lost glass would have to be compatible with TFT processing conditions.

Referring to FIG. 5, yet another alternate embodiment of substrate product 10 is disclosed. This embodiment is similar to the embodiment shown in FIG. 1, in that substrate product 10 is a laminate that includes display substrate 20 and support substrate 30. However, product 10 may be shipped to the LCD manufacturer having a pre-processing layer 310 disposed thereon. Layer 310 includes a silica layer 312 disposed on display substrate 20. A silicon layer 314 is disposed on silica layer 312. Both layers may be formed using chemical vapor deposition (CVD) techniques. The advantage of this embodiment will be apparent after the following discussion.

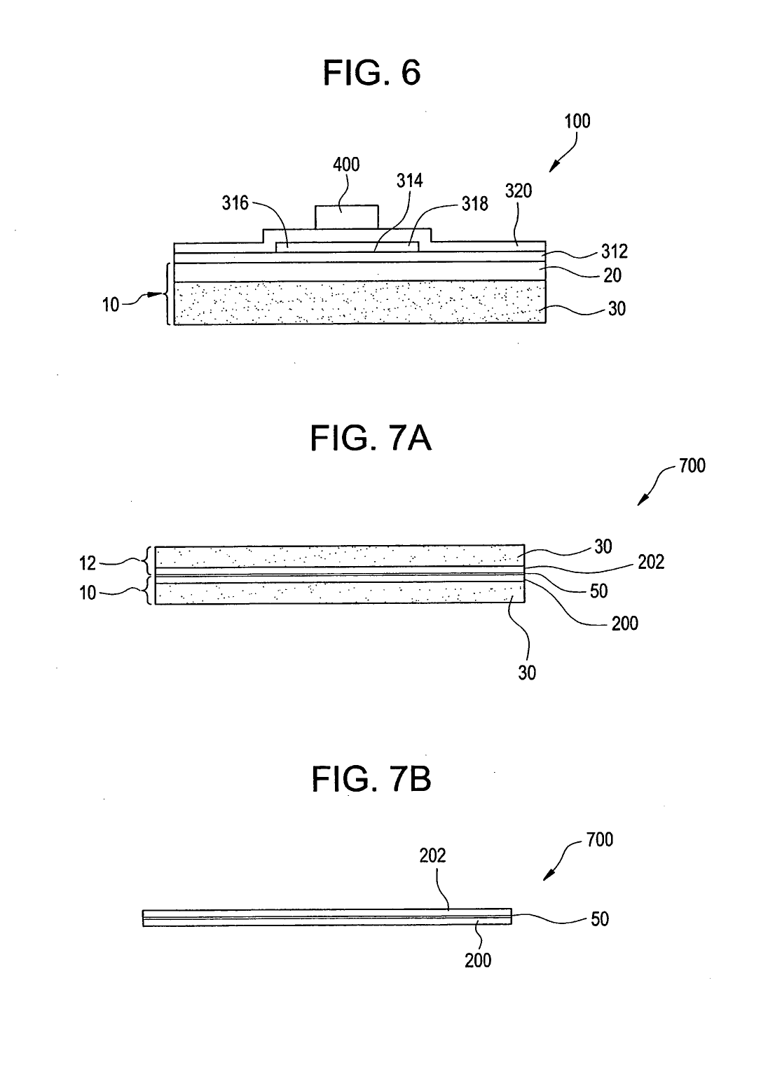

Referring to FIG. 6, a cross-sectional view of a TFT on an active substrate is shown. Active substrate 100 of the present invention includes display substrate 20 disposed on support substrate 30. Using the reference number convention employed in FIG. 5, insulating silica layer 312 is disposed on display substrate 20. Active layer 314, formed from a semiconductor (Si) film, is disposed on insulating layer 312. A gate insulation layer is disposed on active layer 314. Gate 400 is disposed on gate insulator 320 over the center of the active area. Source 316 and drain 318 are formed in the active area. During operation, current flows from the source 316 to the drain 318 when power is applied to the transistor. Pixel actuation is controlled by a circuit coupled to drain 318. The configuration of the TFT transistor 100 shown in FIG. 6 is for illustration purposes, and the present invention should not be construed as being limited to a transistor of this type. Accordingly, FIG. 6 illustrates the use of a sacrificial support layer 30 to enable the fabrication of TFTs on lighter and thinner display substrates having a thickness between 0.1-0.4 mm. Those skilled in the art will understand that substrate product 10 has an overall thickness, weight, and sag characteristics that are compatible with conventional TFT processing. Thus, the present invention may be employed without any significant alteration to TFT manufacturing processes. Once TFT processing is complete, the sacrificial layer may be removed using one of the above described techniques.

FIG. 7A and FIG. 7B are detail views illustrating a method for making an active matrix liquid crystal display panel in accordance with the present invention. As shown in FIG. 7A, an active matrix liquid crystal display panel is produced using substrate product 10 and substrate product 12, both fabricated in accordance with the principles of the present invention. A plurality of thin film transistors are disposed on display substrate 200 of substrate product 10 to produce an active substrate. A color filter is disposed on display substrate 202 on product 12 to produce a color filter substrate. Subsequently, liquid crystal material 50 is placed between active substrate 200 and color filter substrate 202, and sealed with an appropriate material. As shown in FIG. 7B, the support substrates 30 attached to each of the display substrates (200, 202) are removed. To illustrate the advantages of the present invention, it is noted that if display substrate 200 and display 202 each have a thickness of 0.3 mm, the resultant display panel 700 will be 50% lighter than conventional AMLCD panels, since the thicknesses of conventional display substrates are on the order of 0.6-0.7 mm. If display substrate 200 and display substrate 202 each have a thickness of 0.1 mm, the resultant display panel 700 will be approximately 80% lighter than conventional AMLCD panels.

It will be apparent to those skilled in the art that various modifications and variations can be made to the present invention without departing from the spirit and scope of the invention. Thus, it is intended that the present invention cover the modifications and variations of this invention provided they come within the scope of the appended claims and their equivalents.

1-41. (canceled)

42. A substrate product for use in the manufacture of active matrix liquid crystal display panels comprising:
a glass display substrate having a thickness less than about 0.4 mm, the glass of the display substrate being alkali-free and having a strain point greater than 600° C.;
a first sacrificial glass support substrate removably attached to the display substrate, the glass of the support substrate having a strain point greater than 600° C.; and
wherein a coefficient of thermal expansion of the support substrate is within about 5×10⁻⁷/° C. of a coefficient of thermal expansion of the display substrate.

43. The substrate product according to claim 42 wherein the coefficient of thermal expansion of the first sacrificial glass support substrate is between 20×10⁻⁷/° C. and 60×10⁻⁷/° C. over a temperature range of 0° C. to 300° C.

44. The substrate product according to claim 42 wherein the display substrate is attached to the first sacrificial glass support substrate with an adhesive.

45. The substrate product according to claim 42 wherein the display substrate and the first sacrificial glass support substrate were attached at a temperature at which both substrates were in a fluid form.

46. The substrate product according to claim 42 wherein the first sacrificial glass support substrate is removable by chemical dissolution without damage to the display substrate.

47. The substrate product according to claim 42 further comprising a diamond-like coating disposed between the display substrate and the first sacrificial glass support substrate.

48. The substrate product according to claim 42 further comprising a second sacrificial glass support substrate removably attached to the display substrate.

49. The substrate product according to claim 42 further comprising a silica layer disposed on the display substrate, and a semiconductor layer disposed on the silica layer.

50. The substrate product according to claim 42 further comprising a thin film transistor disposed thereon.

51. The substrate product according to claim 50 further comprising a plurality of thin film transistors disposed thereon.

52. A substrate product for use in the manufacture of active matrix liquid crystal display panels comprising:
a glass display substrate; and
a first sacrificial glass support substrate attached to the display substrate and adapted to be removed from the display substrate after the formation of thin film transistors thereon.

53. The substrate product according to claim 52 further comprising a second sacrificial glass support substrate attached to display substrate and adapted to be removed from the display substrate.

54. The substrate product according to claim 52 wherein the first sacrificial glass support substrate is corrugated.

55. The substrate product according to claim 52 wherein a coefficient of thermal expansion of the first sacrificial glass support substrate is within about 5×10⁻⁷/° C. of a coefficient of thermal expansion of the display substrate.

56. The substrate product according to claim 52 further comprising an insulating layer and a semiconductor layer disposed on the display substrate.

57. The substrate product according to claim 52 further comprising a thin film transistor disposed thereon.

58. A substrate product for use in the manufacture of active matrix liquid crystal display panels comprising:
a glass display substrate having a thickness less than about 0.4 mm;
a sacrificial glass support substrate attached to the display substrate and adapted to be removed from the display substrate; and
wherein the display substrate is essentially completely enclosed within the support substrate.

59. The substrate product according to claim 58 wherein the display substrate and the sacrificial glass support substrate were attached at a temperature at which both substrates were in a fluid form.

60. The substrate product according to claim 58 wherein a coefficient of thermal expansion of the support substrate is within about 5×10⁻⁷/° C. of a coefficient of thermal expansion of the display substrate.

61. The substrate product according to claim 58 wherein the coefficient of thermal expansion of the sacrificial glass support substrate is between 20×10⁻⁷/° C. and 60×10⁻⁷/° C. over a temperature range of 0° C. to 300° C.
